(19) United States
(12) Patent Application Publication
(10) Pub. No.: US 2026/0085921 A1
(43) Pub. Date: Mar. 26, 2026

(54) SYSTEM, APPARATUS, AND DEVICE FOR MEASURING AN AMOUNT OF DEPOSITED DIELECTRIC MATERIAL

(71) Applicant: ASM IP Holding B.V., Almere (NL)

(72) Inventors: Hannelore Azora Hemminger, Tempe, AZ (US); Steven Bopp, Chandler, AZ (US); Jereld Lee Winkler, Gilbert, AZ (US)

(21) Appl. No.: 19/332,227

(22) Filed: Sep. 18, 2025

Related U.S. Application Data
(60) Provisional application No. 63/697,829, filed on Sep. 23, 2024.

(51) Int. Cl. G01B 7/06; C23C 16/52

(52) U.S. Cl. CPC G01B 7/085; C23C 16/52

(57) ABSTRACT

Systems, apparatus, and devices for measuring an amount of dielectric material deposited within a reaction chamber are disclosed. The apparatus and devices can be used to measure an amount of deposited material in near real time, such that the measurements can be used to control and/or provide information regarding the systems.

### CROSS-REFERENCE TO RELATED APPLICATIONS

This application is a nonprovisional of, and claims priority to and the benefit of, U.S. Provisional Ser. No. 63/697,829 , filed Sep. 23, 2024 and entitled “SYSTEM, APPARATUS, AND DEVICE FOR MEASURING AN AMOUNT OF DEPOSITED DIELECTRIC MATERIAL,” which is hereby incorporated by reference herein.

### FIELD OF DISCLOSURE

The present disclosure generally relates to systems, apparatus, and devices for measuring an amount of material deposited in, for example, gas-phase reactor systems. More particularly, the disclosure relates to devices suitable for measuring an amount of deposited dielectric material within a gas phase reactor and to apparatus and systems including such devices.

### BACKGROUND OF THE DISCLOSURE

Dielectric films can be used for a variety of applications. For example, in the manufacture of electronic devices, dielectric films or layers can be used as etch stop layers, as masking layers, as insulating layers, and/or as dielectric material in various devices, such as semiconductor devices, capacitors, microelectromechanical systems (MEMS), and the like. As a size of electronic devices generally continues to decrease, control of film thickness and of film quality becomes increasingly desirable.

Dielectric films are often deposited using gas-phase processes, such as chemical vapor deposition (CVD), plasma-enhanced CVD (PECVD), atomic layer deposition (ALD), or the like. In many cases, it may be desirable to know when a deposited amount of dielectric material and/or a deposition rate is within a specified range. For example, a deposition rate that is low may indicate that a temperature is too low, a flow of a precursor and/or reactant is too low, or the like. Deposition rates that are too high can indicate other problems. Accordingly, it is generally desirable to know a deposition rate near real time. Furthermore, it is generally desirable to know a deposition rate on or near a substrate that is processed.

Typical techniques to measure deposition rate or an amount of deposited material include depositing material on a substrate within a gas-phase reactor, removing the substrate from the reactor, and using a separate tool to measure the film thickness. Such techniques are relatively time consuming and cannot provide near real-time information.

A quartz crystal microbalance can be used to measure deposition of dielectric material within a gas-phase reactor. A quartz crystal microbalance can provide relatively high resolution of film thickness measurements. However, there is generally a tradeoff with using a quartz crystal microbalance to measure film thickness: as a sensitivity of the quartz crystal microbalance increases, a fragility of the quartz crystal microbalance also increases.

Specifically, thinner oscillators are typically used to increase sensitivity of a quartz crystal microbalance; the thinner oscillators result in fragile quartz crystal microbalances. Further, quartz crystal microbalances exhibit substantial temperature dependence, because a resonant frequency of the device varies with temperature.

Accordingly, improved devices, apparatus, and systems for in situ measurement of deposited dielectric material are desired. More particularly, devices and apparatus that are less fragile, less dependent on temperature and that can be used to measure deposition of material in near real time within a gas-phase reactor system are desired.

Any discussion of problems and solutions in this section has been provided solely for the purposes of conveying a context for the present disclosure; such discussion should not be taken as an admission that any or all of the discussion was known at the time the invention was made.

### SUMMARY OF THE DISCLOSURE

Various embodiments of the present disclosure provide devices, apparatus, and/or systems for measuring an amount of dielectric material deposited in a reaction chamber. The devices, apparatus, and/or systems described herein are suitable for use in a variety of gas-phase processes, such as chemical vapor deposition processes, including plasma-enhanced chemical vapor deposition processes, and cyclical deposition processes, such as atomic layer deposition, including plasma-enhanced cyclical deposition processes.

In accordance with various embodiments of the disclosure, an apparatus for measuring an amount of deposited dielectric material includes a device, including a substrate comprising an insulating material surface, a first conductive plate formed on the insulating surface, a second conductive plate formed on the insulating surface, a (e.g., first) channel between the first conductive plate and the second conductive plate, and a capacitance measurement device electrically coupled to the device—e.g., to the first conductive plate and the second conductive plate. In accordance with various aspects of these embodiments, one or more of the first conductive plate and the second conductive plate include a plurality of protrusions. Additionally or alternatively, the channel can comprise a substantially annular shape. In some cases, the channel comprises a serpentine shape. In accordance with further examples, a width of the channel varies along at least a portion of a length of the channel. For example, the width of the channel can continually vary over the portion of the length. In some cases, the device is configured such that a capacitance of the device varies approximately linearly with an amount (e.g., a thickness) of dielectric material deposited on a surface of the device. In accordance with further aspects, the capacitance measurement device is or includes a capacitance bridge. In accordance with yet additional aspects, the apparatus can include one or more additional pairs of conductive plates with a respective channel between each pair of conductive plates. A width of the channels can be different to allow for desired sensitivity and resolution. The apparatus can further comprise a controller coupled to the capacitance measurement device. The controller can be configured to determine the amount of deposited dielectric material on the substrate.

In accordance with further examples, a system comprises one or more reaction chambers and a device or apparatus for measuring an amount of dielectric material deposition within a reaction chamber of the one or more reaction chambers. For example, the system can include the one or more reaction chambers, a gas distribution system fluidly coupled to the one or more reaction chambers, a controller, and a device for measuring an amount of dielectric material deposition within a reaction chamber of the one or more reaction chambers. The system can further include a capacitance measurement device electrically coupled to the device for measuring an amount of dielectric material deposition. The controller can be configured to receive a signal from the capacitance measurement device and to determine the amount of dielectric material deposition within the reaction chamber. The system can further include a susceptor within the reaction chamber. The device can be placed on or proximate a susceptor within the reaction chamber. In accordance with additional examples, the controller can be configured to determine when a predetermined amount of dielectric material has been deposited and automatically provide an indication to a user interface to indicate that the predetermined amount of dielectric material has been deposited and/or compare a measured amount to a target amount and automatically change one or more process conditions if the measured amount differs from the target amount by more than a predetermined amount.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a system in accordance with various embodiments of the disclosure.

FIG. 2 illustrates an apparatus in accordance with exemplary embodiments of the disclosure.

FIG. 3 illustrates an apparatus in accordance with exemplary embodiments of the disclosure.

FIG. 4 illustrates another apparatus in accordance with exemplary embodiments of the disclosure.

FIG. 5 illustrates a device in accordance with exemplary embodiments of the disclosure.

FIG. 6 illustrates yet another apparatus in accordance with exemplary embodiments of the disclosure.

FIG. 7 illustrates simulated capacitance measurements versus an amount of material deposited in accordance with exemplary embodiments of the disclosure.

FIG. 8 illustrates simulated dC/dep, F/m data for target behavior, a constant gap device, and a variable gap device.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to systems, apparatus, and devices to measure an amount of dielectric material that is deposited within a reaction chamber. The systems, apparatus, and devices are relatively insensitive to temperature differences (e.g., as compared to quartz crystal microbalances), are relatively durable, and can be used to provide near real-time (e.g., less than 0.5 seconds) measurements corresponding to an amount of dielectric material deposited.

As used herein, the term substrate may refer to any underlying material or materials, including and/or upon which one or more layers can be deposited. A substrate can include a bulk material, such as silicon (e.g., single-crystal silicon), and can have an insulating layer formed thereon. For example, the substrate can include an insulating surface.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. For example, the term about can refer to +/−20, 10, 5, 2, or 1 percent of a value. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

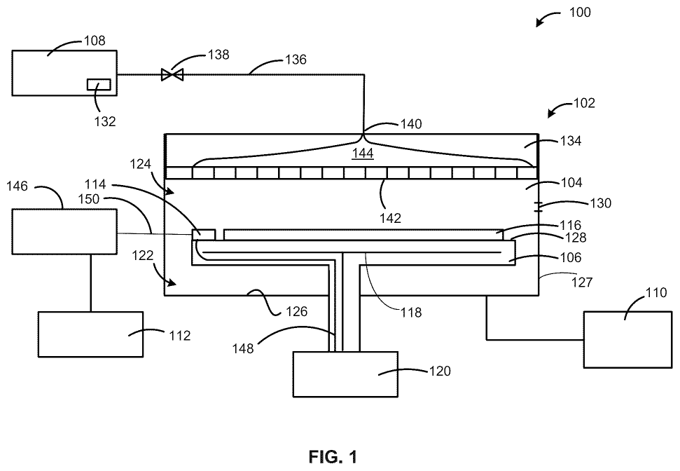

Turning now to the figures, FIG. 1 illustrates a system 100 in accordance with embodiments of the disclosure. System 100 includes one or more reaction chambers 102, each including a reaction space 104, a susceptor 106, a gas distribution system 108, an exhaust source 110, controller 112, and a device 114 for measuring an amount of dielectric material deposition. Although not illustrated, system 100 may additionally include direct and/or remote plasma and/or thermal excitation apparatus for one or more reactants provided to or within reaction chamber 102.

Reaction chamber(s) 102 can be or include a reaction chamber suitable for gas-phase reactions. Reaction chamber(s) 102 can be formed of suitable material, such as quartz, metal, or the like, and can be configured to retain one or more substrates 116 for processing. Reaction chamber(s) 102 can be configured as a CVD reactor, a cyclical deposition process reactor (e.g., a cyclical CVD reactor), an ALD reactor, or the like, any of which may include plasma apparatus, such as direct and/or remote plasma apparatus. System 100 can include any suitable number of reaction chamber(s) 102 and can optionally include one or more substrate handling systems.

Reaction chamber(s) 102 can be used to deposit material onto a surface of a substrate 116. By way of example, one or more reaction chamber(s) 102 can be configured to deposit dielectric material, such as non-conductive metal and/or metalloid oxides and/or nitrides, such as Group II, III, IV and/or V metal and/or metalloid oxides or nitrides. By way of particular examples, the dielectric material can be or include a metal oxide or nitride that includes one or more of Al, Hf, Zr, Ta, Ti, or the like. Exemplary dielectric materials can have a dielectric constant between 3 and 30 or between 3.7 and 28. As used herein, non-conductive can mean a resistivity of greater than 10,000 μΩ/cm.

In some cases, one or more reaction chamber(s) 102 can be dedicated to deposition. In other cases, one or more reaction chamber(s) 102 can be configured to perform multiple processes—e.g., deposition and one or more of an etch, clean, and/or treatment processes.

Susceptor 106 is configured to retain substrate 116 in place during processing. One or more sections of susceptor 106 can be heated, cooled, or be at ambient process temperature during processing. In accordance with examples of the disclosure, susceptor 106 includes a temperature regulating device 118, such as a heater (e.g., a resistive heater), and/or a cooling device (e.g., a conduit for a cooling medium, such as chilled water).

Susceptor 106 can be formed of any suitable material, such as ceramic material, such as boron nitride, aluminum nitride, quartz, and ceramic-coated materials, such as ceramic-coated metals. As noted above, susceptor 106 can also include resistive heating material.

Exemplary materials suitable for resistive heating material include tungsten (W), nichrome (NiCr), cupronickel (CuNi), graphite, molybdenum disilicide (MoSi₂) or any other suitable heater material. The resistive heating material can be coated onto (e.g., patterned onto), for example, ceramic or ceramic-coated metal. Susceptor 106 can include an additional protective layer formed overlying the resistive heating material. The protective layer can be formed of, for example, ceramic material.

In the illustrated example, system 100 includes a mechanism 120 to move susceptor 106 from a lower chamber region 122 to upper chamber region 124. Mechanism 120 can include any suitable apparatus capable of moving susceptor 106 relative to a bottom chamber wall 126. By way of example, mechanism 120 includes a servo motor to drive susceptor 106 along a vertical axis. Mechanism 120 can suitably reside outside reaction chamber 102.

As Illustrated, reaction chamber 102 includes reaction space 104 defined, in part, by a chamber wall 127 and an upper surface 128 of susceptor 106 when susceptor 106 is in an upper or processing position. Chamber wall 127 can include a gate valve opening 130. Substrate 116 can be placed on or removed from surface 128 when susceptor 106 is in a lower or load/unload position, as illustrated in FIG. 1.

Gas distribution system 108 is fluidly coupled to the one or more reaction chamber(s) 102 and is configured to provide one or more gases to reaction space 104. Gas distribution system 108 can include one or more gas sources 132, a gas distribution device 134, and one or more lines 136 spanning between gas sources 132 and gas distribution device 134. As illustrated, one or more lines 136 can include a valve 138 (e.g., in each line) to regulate flow of gas between gas sources 132 and gas distribution device 134. Gas distribution device 134 is configured to distribute one or more gases to reaction space 104 during substrate processing. Gas distribution device 134 can include an inlet 140 and a plurality of holes 142 coupled to a plenum 144.

Exhaust source 110 can be or include one or more vacuum pumps. By way of example, exhaust source 110 can include one or more of a turbomolecular pump and a cryopump.

Controller 112 can be configured to perform various functions and/or steps as described herein. Controller 112 can include one or more microprocessors, memory elements, and/or switching elements to perform the various functions. Although illustrated as a single unit, controller 112 can alternatively comprise multiple devices. In accordance with examples of the disclosure, controller 112 is configured to receive a signal from the capacitance measurement device 146 and to determine the amount of dielectric material deposition within the reaction chamber. Controller 112 can further be configured to determine when a predetermined amount of dielectric material has been deposited and automatically provide an indication to a user interface to indicate that the predetermined amount of dielectric material has been deposited. Additionally or alternatively, controller 112 can be configured to compare a measured amount to a target amount and automatically change one or more process conditions if the measured amount differs from the target amount by more than a predetermined amount. For example, controller 112 can be configured to automatically change a deposition time or temperature or a flowrate of one or more gases to reaction space 104.

Device 114 is configured to measure an amount of dielectric material deposition anywhere within a reaction chamber of the one or more reaction chamber(s) 102. Device 114 can suitably be placed within reaction space 104, such as on or proximate surface 128 of susceptor 106 or otherwise near (e.g., within about 100 mm or 50 mm) substrate 116. In accordance with examples, during a deposition process, device 114 is at or within about five percent of a temperature of a substrate or other surface of which is it desirable to measure an amount of dielectric material deposited thereon. In the illustrated example, device 114 is on susceptor 106. In this case, device 114 can move up and down as susceptor 106 moves up and down and wires 148 can be used to couple device 114 to capacitance measurement device 146. Alternatively, wires 150 can be used.

As set forth in more detail below, system 100 can also include capacitance measurement device 146. Capacitance measurement device 146 can be electrically coupled to device 114 and controller 112, which can both reside outside reaction chamber 102. In accordance with examples of the disclosure, an apparatus for measuring an amount of deposited dielectric material includes a device, such as device 114, and a capacitance measurement device, such as a capacitance measurement device 146.

During deposition of dielectric material, device 114 and/or an apparatus as described herein can be used to measure an amount (e.g., a thickness) of dielectric material deposited on a surface by measuring a change in capacitance of device 114. Capacitance measurement device 146 (e.g., a capacitance bridge) can measure capacitance change down to the greater of about 0.5 attofarads or about 0.2 ppm. For a dielectric material with relative permittivity of 10, a sub-Angstrom deposition resolution can be achieved for a measurement range of 100-150 micrometers thickness of deposited dielectric material. This resolution can increase during a life of the device, because the sensitivity increases with the amount of material deposited.

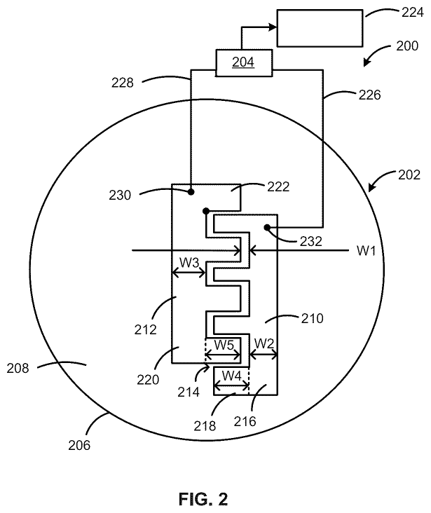

FIG. 2 to FIG. 6 illustrate exemplary apparatus and devices suitable for measuring an amount of dielectric material deposition. The examples described below are merely illustrative and, unless otherwise noted, are not meant to limit the scope of the invention.

FIG. 2 illustrates an apparatus 200 for measuring an amount of deposited dielectric material. Apparatus 200 includes a device 202 for measuring an amount of dielectric material deposition and a capacitance measurement device 204.

Device 202 for measuring an amount of dielectric material deposition includes a substrate 206 that includes an insulating material surface or insulating surface 208, a first conductive plate 210 formed on insulating surface 208, a second conductive plate 212 formed on insulating surface 208, and a channel 214 between first conductive plate 210 and second conductive plate 212.

Substrate 206 can be or include any suitable substrate, such as a substrate described above. Insulating surface 208 can be or include, for example, quartz, aluminum oxide, and/or any of the dielectric materials described above. Insulating surface 208 can be formed by, for example, thermal oxidation or deposition of the insulating material.

First conductive plate 210 and second conductive plate 212 can be formed (e.g., directly) on insulating surface 208. First conductive plate 210 and second conductive plate 212 can be formed of conductive material, such as material having a resistivity less than 1000 or less than 500 μΩ/cm. Particular exemplary materials include metals, metal alloys, and conductive ceramics, such as 316 stainless steel, and materials including one or more of Al and Ti. First conductive plate 210 and second conductive plate 212 can have a height (thickness) extending from insulating surface 208 that is from about 100 nm to about 10 mm or about 1000 nm to about 1 mm.

Channel 214 that is between the first conductive plate and the second conductive plate can have a width (W1) that is, for example, between about 100 nm and about 5 mm or between about 1 μm and about 5 mm. Width W1 can be substantially constant along channel 214 or can vary. In the example illustrated in FIG. 2, channel 214 includes a serpentine shape.

In the illustrated example, first conductive plate 210 includes a base 216 and a plurality of first plate protrusions 218 extending from base 216. Similarly, second conductive plate 212 includes a base 220 and a plurality of second plate protrusions 222 extending from base 220. In some cases, a number of first and/or second plate protrusions can be two or more, four or more, or six or more and/or can be less than or equal to ten, eight, or six. As illustrated, one or more of the second plate protrusions 222 can be interposed between two first plate protrusions 218.

A width (W2) of base 216 or a width (W3) of base 220 can be for example, between about 100 nm and about 5 mm or between about 1 μm and about 5 mm. A width (W4) of first plate protrusions 218 and/or a width (W5) of second plate protrusions 222 can also be between about 100 nm and about 5 mm or between about 1 μm and about 5 mm.

First conductive plate 210 and second conductive plate 212 can be formed on insulating surface 208 using any suitable technique. For example, first conductive plate 210 and/or second conductive plate 212 can be formed using, deposition (e.g., laser, water jet, wire EDM, or CVD techniques) and etch techniques (e.g., using photolithography masking), selective deposition techniques, printed circuit board manufacturing techniques, or the like.

Capacitance measurement device 204 is electrically coupled to first conductive plate 210 and second conductive plate 212. For example, a first conductive line 226 can be coupled to first conductive plate 210 at contact 232 and to capacitance measurement device 204, and a second conductive line 228 can be coupled to second conductive plate 212 at contact 230 and capacitance measurement device 204. By way of further example, capacitance measurement device 204 can be or include a capacitance bridge.

Apparatus 200 can also include a controller 224 coupled to capacitance measurement device 204. By way of example, controller 224 can be configured to determine the amount of deposited dielectric material on the substrate (e.g., substrate 116 or substrate 206). Controller 224 can be the same or similar to controller 112 described above.

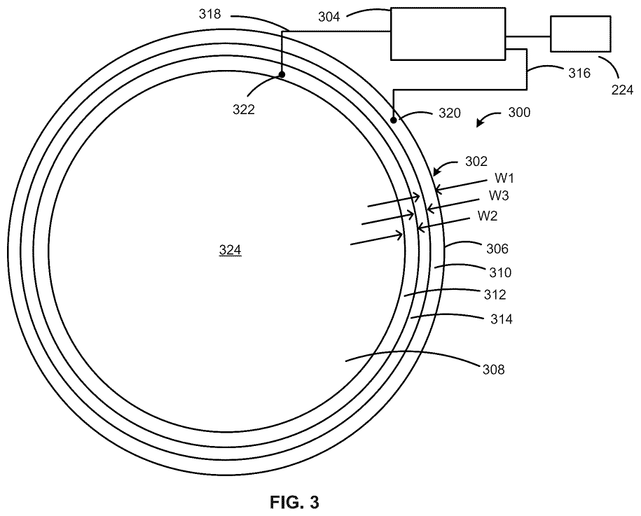

FIG. 3 illustrates another apparatus 300 for measuring an amount of deposited dielectric material. Apparatus 300 includes a device 302 for measuring an amount of dielectric material deposition and a capacitance measurement device 304.

Device 302 for measuring an amount of dielectric material includes a substrate 306 that includes an insulating material surface or insulating surface 308, a first conductive plate 310 formed on insulating surface 308, a second conductive plate 312 formed on insulating surface 308, and a channel 314 between first conductive plate 310 and second conductive plate 312. Substrate 306 and insulating surface 308 can be the same as substrate 206 and insulating surface 208 described above.

First conductive plate 310, second conductive plate 312, and channel 314 can be similar to first conductive plate 210, second conductive plate 212, and channel 214, except first conductive plate 310, second conductive plate 312, and channel 314 include an annular or substantially annular shape. A radius of the annular shape can be selected, such that, for example, a substrate can reside on a center portion 324 of device 302.

A width of first conductive plate 310, a width of second conductive plate 312, and a width of channel 314 can be the same or similar to the width of base 216, base 220, and channel 214 described above. A height of each of first conductive plate 310 and second conductive plate 312 can also be the same as the height of first conductive plate 210 and second conductive plates 212 described above.

Capacitance measurement device 304 can be the same or similar to capacitance measurement device 204. Capacitance measurement device 304 can be electrically coupled to first conductive plate 310 using a first wire 316 and an electrical contact 320 and electrically coupled to second conductive plate 312 using a second wire 318 and an electrical contact 322. As illustrated, capacitance measurement device 304 can be coupled to controller 224.

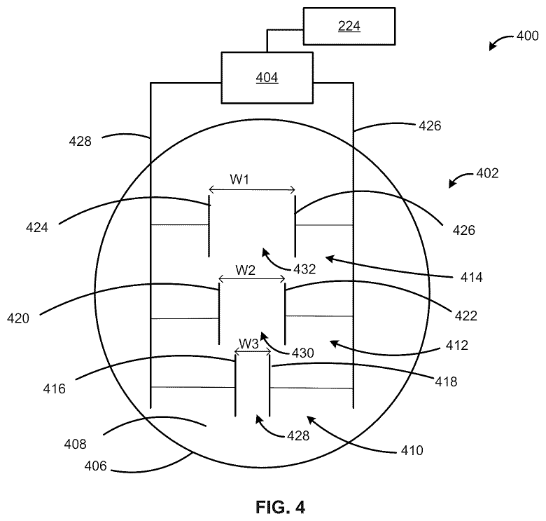

FIG. 4 illustrates another apparatus 400 for measuring an amount of deposited dielectric material. Apparatus 400 includes a device 402 for measuring an amount of dielectric material deposition and a capacitance measurement device 404. Apparatus 400 is similar to apparatus 300, except device 402 includes a plurality of pairs of conductive plates, rather than a single pair of conductive plates and capacitance measurement device 404 can be configured to measure capacitance of the plurality of pairs of conductive plates.

In the illustrative example, device 402 includes an insulating material surface or insulating surface 408 on a surface of a substrate 406; a first pair 410 of (e.g., first and second) conductive plates 416, 418; a second pair 412 of (e.g., third and fourth) conductive plates 420, 422; and a third pair 414 of (e.g., fifth and sixth) conductive plates 424, 426. Each pair 410, 412, 414 of conductive plates 416, 418; 420, 422; and 424, 426 includes a corresponding channel 428, 430, 432 therebetween. A height of conductive plates 416-426 can be as described above. A width of each of conductive plates 416-426 can be as described above—e.g., in connection with W2 or W3 above. Further, each pair 410, 412, 414 of conductive plates 416-426 can include (e.g., interposed) protrusions and/or can be of annual shape as described above. Substrate 406 and insulating surface 408 can be the same as substrate 306 and insulating surface 308 described above. In the illustrated example, a width W1, W2, W3 of two or more channels 428, 430, 432 can be different. Such a configuration can allow greater resolution of an amount of material deposited—e.g., down to about 0.1 Angstroms. Each pair 410, 412, 414 of conductive plates 416-426 can be (e.g., selectively) coupled to capacitance measurement device 404, which can be coupled to a controller 224.

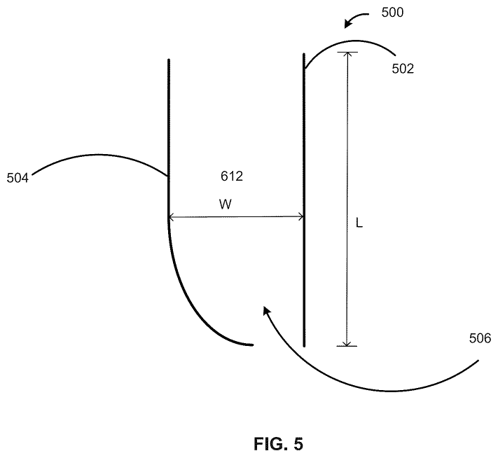

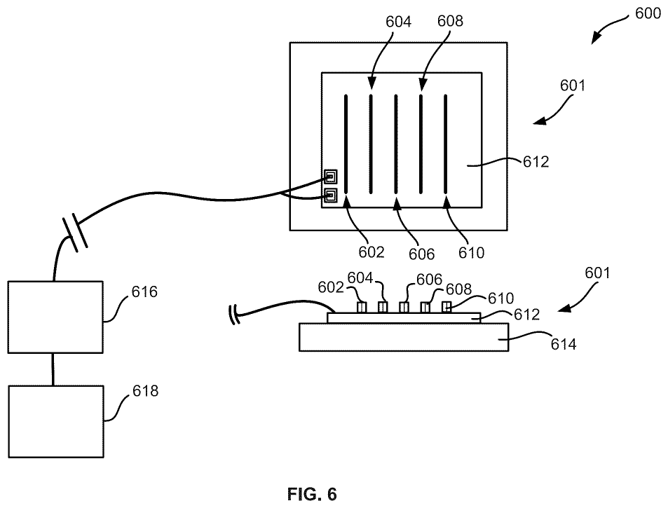

FIG. 5 and FIG. 6 illustrate an apparatus 600 in accordance with further examples of the disclosure. FIG. 6 illustrates a top view and a side view of apparatus 600 that includes a device 601 that includes a plurality of pairs 602-610 of conductive plates formed on an insulating material surface or insulating surface 612 on a substrate 614. Although separately illustrated, substrate 614 can include insulating surface 612, and in some cases, substrate 614 can be formed of or consist of the insulating material/surface. Although illustrated with a plurality of pairs 602-610 of conductive plates, device 601 can include just one pair (e.g., pair 602) of conductive plates. Apparatus 600 can further include a capacitance measurement device 616 and/or a controller 618. Each of the plurality of pairs 602-610 of conductive plates can be coupled to capacitance measurement device 616, which can be coupled to controller 618. Substrate 614 and insulating surface 612 can be the same as substrate 206 and insulating surface 208 described above.

FIG. 5 illustrates top view of a single pair 500 of conductive plates that are suitable for any of pairs 602-610 of conductive plates. Pair 500 of conductive plates includes a first conductive plate 502 formed on insulating surface 612, a second conductive plate 504 formed on insulating surface 612, and a channel 506 between first conductive plate 502 and second conductive plate 504.

As illustrated, a width (W) of the channel 506 varies (e.g., non-linearly) along at least a portion of a length L of the channel 506. In accordance with further examples, the width W of channel 506 does not substantially vary over another portion of the length—e.g., the width may become asymptotic. In accordance with further examples of the disclosure, a first conductive plate 502 and second conductive plate 504 can be considered a capacitor with an infinite number of different widths W along length L. In accordance with further examples, device 601 or, more particularly, one or more pairs of conductive plates (e.g., 502, 504) of device 601 are configured, such that a capacitance of device or pair varies approximately linearly with an amount of dielectric material deposited on a surface of the device. With this design, capacitance of respective pairs (e.g., conductive plates 502, 504) can be linear relative to an amount (e.g., a thickness) of material deposited on device 601 without sacrificing device size, sensitivity, and/or measurement range that might otherwise be affected with a constant gap-width device.

Capacitance measurement device 616 can be as described above. Controller 618 can be similar to controller 112, 224, described above. For example, controller 618 coupled to 601 can be configured to receive a signal from capacitance measurement device 616 to thereby determine a measured amount of deposited material on device 601 and/or to perform other functions noted herein.

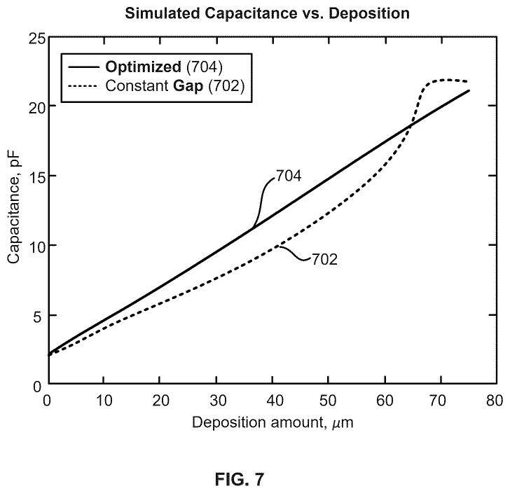

FIG. 7 illustrates simulated capacitance measurements versus an amount of material deposited for a device that is about 0.5 inches by about 0.5 inches. Target sensitivity is 0.25 pF/μm thickness of material deposited or about 25 aF/Angstrom. As illustrated, data for a constant gap device (702) varies non-linearly, while data for a variable gap device (704) is substantially linear.

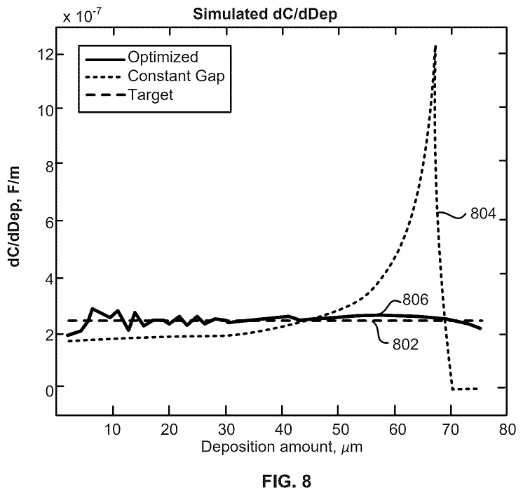

FIG. 8 illustrates simulated dC/dep, F/m data for target behavior (802), a constant gap device (804), and a variable gap device (806). As illustrated, data for the variable gap device is relatively close to data for the target data.

Although exemplary embodiments of the present disclosure are set forth herein, it should be appreciated that the disclosure is not so limited. For example, although the systems, apparatus, and devices are described in connection with various specific configurations, the disclosure is not necessarily limited to these examples. Various modifications, variations, and enhancements of the exemplary systems, apparatus, and devices set forth herein may be made without departing from the spirit and scope of the present disclosure.

The subject matter of the present disclosure includes all novel and nonobvious combinations and subcombinations of the various systems, assemblies, reactors, components, and configurations, and other features, functions, acts, and/or properties disclosed herein, as well as any and all equivalents thereof.

1. An apparatus for measuring an amount of deposited dielectric material, the apparatus comprising:
a substrate comprising an insulating surface;
a first conductive plate formed on the insulating surface;
a second conductive plate formed on the insulating surface;
a first channel between the first conductive plate and the second conductive plate; and
a capacitance measurement device electrically coupled to the first conductive plate and the second conductive plate,
wherein at least one of:
the first conductive plate comprises a plurality of first plate protrusions, or
the first channel comprises an annular shape.

2. The apparatus of claim 1, wherein the capacitance measurement device comprises a capacitance bridge.

3. The apparatus of claim 1, further comprising a third conductive plate, a fourth conductive plate and a second channel therebetween, wherein a width of the second channel differs from a width of the first channel.

4. The apparatus of claim 3, wherein the third conductive plate and the fourth conductive plate are coupled to the capacitance measurement device.

5. The apparatus of claim 1, further comprising a controller coupled to the capacitance measurement device, wherein the controller is configured to determine the amount of the dielectric material deposited on the substrate.

6. The apparatus of claim 1, wherein the plurality of first plate protrusions comprises four or more protrusions.

7. The apparatus of claim 1, wherein the second conductive plate comprises a plurality of second plate protrusions.

8. The apparatus of claim 7, wherein one or more of the second plate protrusions are interposed between two first plate protrusions.

9. The apparatus of claim 1, wherein the first channel comprises the annular shape.

10. The apparatus of claim 1, wherein the first channel comprises a serpentine shape.

11. A system comprising:
one or more reaction chambers;
a gas distribution system fluidly coupled to the one or more reaction chambers;
a controller; and
a device for measuring an amount of dielectric material deposition within a reaction chamber of the one or more reaction chambers, the device comprising:
an insulating surface;
a first conductive plate formed on the insulating surface;
a second conductive plate formed on the insulating surface; and
a channel between the first conductive plate and the second conductive plate,
wherein a width of the channel varies along at least a portion of a length of the channel,
wherein the device is within the reaction chamber,
wherein the device is electrically coupled to a capacitance measurement device, and
wherein the controller is configured to receive a signal from the capacitance measurement device and to determine the amount of the dielectric material deposited within the reaction chamber.

12. The system of claim 11, wherein the width of the channel continually varies over the portion of the length.

13. The system of claim 12, wherein a width of the channel does not substantially vary over another portion of the length.

14. The system of claim 11, wherein the device is configured such that a capacitance of the device varies approximately linearly with the amount of the dielectric material deposited on a surface of the device.

15. The system of claim 14, wherein the amount of the dielectric material deposited corresponds to a thickness of the dielectric material deposited on the surface of the device.

16. A system comprising:
one or more reaction chambers;
an apparatus for measuring an amount of deposited dielectric material deposited in a reaction chamber of the one or more reaction chambers, the apparatus comprising:
a substrate comprising an insulating surface;
a first conductive plate formed on the insulating surface;
a second conductive plate formed on the insulating surface;
a channel between the first conductive plate and the second conductive plate; and
a capacitance measurement device electrically coupled to the first conductive plate and the second conductive plate;
the system further comprising a controller configured to receive a signal from the capacitance measurement device to thereby determine a measured amount of the dielectric material deposited in the reaction chamber.

17. The system of claim 16, wherein the substrate is placed on or proximate a susceptor within the reaction chamber.

18. The system of claim 16, wherein the controller is further configured to determine when a predetermined amount of the dielectric material has been deposited and automatically provide an indication to a user interface to indicate that the predetermined amount of the dielectric material has been deposited.

19. The system of claim 16, wherein the controller is further configured to compare the measured amount to a target amount and automatically change one or more process conditions if the measured amount differs from the target amount by more than a predetermined amount.

20. The system of claim 16, wherein a width of the channel varies along at least a portion of a length of the channel.
